(19) United States
(12) Patent Application Publication
(10) Pub. No.: US 2025/0098438 A1
(43) Pub. Date: Mar. 20, 2025

(54) DISPLAY PANEL AND DISPLAY APPARATUS

(71) Applicant: Hefei Visionox Technology Co., Ltd., Hefei (CN)

(72) Inventors: Liusong NI, Hefei (CN); Zhiwei ZHOU, Hefei (CN); Yiming XIAO, Hefei (CN); Yuan YAO, Hefei (CN); Yi-Yu LAI, Hefei (CN); Xuejing ZHU, Hefei (CN)

(73) Assignee: Hefei Visionox Technology Co., Ltd., Hefei (CN)

(21) Appl. No.: 18/969,942

(22) Filed: Dec. 5, 2024

Related U.S. Application Data
(63) Continuation of application No. PCT/CN2024/099072, filed on Jun. 13, 2024.

(30) Foreign Application Priority Data
Jun. 13, 2023 (CN) 202310707209.0
Dec. 8, 2023 (CN) 202311694025.1

(51) Int. Cl. H10K 59/122

(52) U.S. Cl. CPC H10K 59/122

(57) ABSTRACT

A display panel, including: a base plate; a plurality of first electrodes being distributed in an array on a side of the base plate and having first edge areas; an isolation structure, provided on a side of the base plate, located on a same side of the base plate as the first electrodes, enclosing a plurality of isolation openings and insulated from the first electrodes, at least part of which are exposed from the isolation openings, the isolation structure includes isolation walls with first surfaces away from the base plate and second surfaces facing the base plate, as well as first side surfaces connecting the first surfaces and the second side surfaces, and at least part of orthographic projections of the first edge areas on the base plate are staggered with orthographic projections of the first side surface on the base plate.

### CROSS-REFERENCE TO RELATED APPLICATION

The present application is a continuation application of International Application No. PCT/CN2024/099072, filed on Jun. 13, 2024, which claims priority to Chinese Patent Applications No. 202310707209.0 filed on Jun. 13, 2023, titled “DISPLAY PANEL AND DISPLAY APPARATUS”, and Chinese Patent Application No. 202311694025.1 filed on Dec. 8, 2023, titled “DISPLAY PANEL AND MANUFACTURING METHOD THEREOF, AND DISPLAY APPARATUS”, which are incorporated herein by reference in their entireties.

### TECHNICAL FIELD

The present application relates to the technical field of display technology, and in particular to a display panel and a display apparatus.

### BACKGROUND

Technologies of Organic Light-emitting Display (OLED) and flat display devices based on Light-emitting Diode (LED) or the like have been widely used in various consumer electronic products such as mobile phones, televisions, laptops, and desktops, etc. due to their advantages of higher imaging quality, power saving, thinner device body, and wider range of application, and become the mainstream of display devices.

However, the process performance of current OLED display products needs to be improved.

### SUMMARY

Embodiments of the present application provide a display panel and a display apparatus, aiming to improve the process performance of the display panel.

An embodiment of the present application provides a display panel, comprising a base plate, a plurality of first electrodes distributed in an array on a side of the base plate and having first edge areas; an isolation structure, provided on a side of the base plate, located on a same side of the base plate as the first electrodes, enclosing a plurality of isolation openings and insulated from the first electrodes, at least part of which are exposed from the isolation openings, wherein the isolation structure comprises isolation walls comprising first surfaces away from the base plate and second surfaces facing the base plate in a thickness direction of the display panel, as well as first side surfaces connecting the first surfaces and the second side surfaces, and orthographic projections of at least part of the first edge areas on the base plate are staggered with orthographic projections of the first side surfaces on the base plate.

Furthermore, orthographic projections of the first edge areas on the base plate are staggered with orthographic projections of the isolation walls on the base plate; the orthographic projections of the first electrodes on the base plate are located within orthographic projections of the isolation openings on the base plate.

Furthermore, the isolation structure further comprises barrier parts provided on sides of the isolation walls away from the base plate, orthographic projections of the isolation walls on the base plate being located within orthographic projections of the barrier parts on the base plate.

An embodiment of the first aspect of the present application further provides a display panel, comprising: a base plate; first electrodes located on a side of the base plate; insulating layers located on sides of the first electrodes away from the base plate and enclosing pixel openings, from which the first electrodes at least partially expose; an isolation structure provided on sides of the insulating layers away from the base plate; wherein the isolation structure comprises isolation walls comprising first surfaces away from the base plate, second surfaces facing the base plate, and first side surfaces connecting the first surfaces and the second surfaces, surfaces of the insulating layers away from the base plate comprising flat areas, orthographic projections of the first side surfaces on the base plate being located within orthographic projections of the flat areas on the base plate.

An embodiment of the first aspect of the present application further provides a display panel, comprising: a base plate comprising: pixel circuits and first via holes; first electrodes, located on a side of the base plate and sides of the first via holes away from the pixel circuits, and electrically connected with the pixel circuits via the first via holes; an isolation structure, provided on a side of the base plate and located on the same side of the base plate as the first electrodes, enclosing a plurality of isolation openings, and insulated from the first electrodes, at least part of which is exposed from the isolation openings, wherein the isolation structure comprises isolation walls, orthographic projection of which on the base plate are staggered with orthographic projections of the first via holes on the base plate.

In the display panel of the embodiment of the present application, the display panel comprises a base plate, a plurality of first electrodes and an isolation structure, the first electrodes are distributed in an arrays on a side of the base plate, and the plurality of first electrodes are used to drive a plurality of light-emitting functional portions of the display panel to emit light for display. The first electrodes have first edge areas, which will affect the flatness of the subsequent film layer away from the base plate surface. The isolation structure and the first electrodes are provided on the same side of the base plate, the isolation structure encloses to form isolation openings, and at least part of the first electrodes are exposed from the isolation openings, so that the isolation openings can be used to accommodate the light-emitting functional portions, and the first electrodes exposed from the isolation openings can drive the light-emitting functional portions in the isolation openings to emit light. The isolation structure comprises isolation walls comprising first side surfaces, at least part of the orthographic projections of the first edge areas on the base plate are staggered with the orthographic projection of the first side surfaces on the base plate, so that at least part of the first edge areas will not affect the flatness of the first side surfaces, which is convenient for the subsequent film layers to overlap on the first side surfaces, thereby improving the process performance of the display panel.

### BRIEF DESCRIPTION OF THE DRAWINGS

In order to more clearly illustrate the technical solution of embodiments of the present application, the following is a brief introduction to the drawings required for use in the embodiments of the present application. For those skilled in the art, other drawings can be obtained based on these drawings without any creative work.

FIG. 1 is a top view structural schematic diagram of a display panel according to some embodiments of the present application;

FIG. 2 shows an enlarged top view structural schematic diagram of the display panel in area B in FIG. 1;

FIG. 3 shows an exemplary cross-sectional view of the display panel in FIG. 2 along section AA;

FIG. 4 shows another exemplary cross-sectional view of the display panel in FIG. 2 along section AA;

FIG. 5 shows another exemplary cross-sectional view of the display panel in FIG. 2 along section AA;

FIG. 6 shows another exemplary cross-sectional view of the display panel in FIG. 2 along section AA;

FIG. 7 shows another exemplary cross-sectional view of the display panel in FIG. 2 along section AA;

FIG. 8 shows a partial cross-sectional view of a display panel in an example;

FIG. 9 shows a partial cross-sectional view of a display panel in another example;

FIG. 10 shows an enlarged top view schematic structural diagram of the display panel in area B in FIG. 1 in another example;

FIG. 11 shows a partial cross-sectional view of a display panel in another example;

FIG. 12 shows a partial cross-sectional view of a display panel in another example;

FIG. 13 shows a partial cross-sectional view of a display panel in another example;

FIG. 14 shows a partial cross-sectional view of a display panel in another example;

FIG. 15 shows a partial cross-sectional view of a display panel in another example;

FIG. 16 shows a cross-sectional view of the display panel in FIG. 2 at section AA in another example;

FIG. 17 shows a cross-sectional view of the display panel in FIG. 2 at section AA in another example; and

FIG. 18 is a partial enlarged structural schematic diagram of FIG. 17.

### REFERENCE NUMERALS

10. display panel; 30. auxiliary electrode; 31. transparent conductive connecting portion;
100. base plate; 110. pixel circuit; 120. first via hole;
200. first electrode; 210. first gap; 220. first edge area; 230. first top surface; 240. first bottom surface; 250. first side wall;
300. first insulating layer; 310. pixel opening; 320. first recess; 330. fifth surface; 340. sixth surface; 350. pixel defining portion; 301. second insulating layer; 302. flat area; 303. first area; 304. second area;
400. isolation structure; 410. second recess; 420. isolation wall; 421. third recess;
422. first surface; 423. second surface; 430. barrier part; 460. isolation opening; 470. first side surface; 480. light transmission hole;
500. light-emitting functional layer; 510. light-emitting functional portion;
600. second electrode;
AA. display area; Z. thickness direction of the display panel.

### DETAILED DESCRIPTION

The features and exemplary embodiments of various aspects of the present application will be described in detail below. In order to make the purpose, technical solutions and advantages of the present application clearer, the present application will be further described in detail below in conjunction with the accompanying drawings and specific embodiments. It should be understood that the specific embodiments described herein are only intended to explain the present application, rather than to limit the present application. For those skilled in the art, the present application can be implemented without the need for some of these specific details. The following description of the embodiments is only to provide a better understanding of the present application by illustrating the examples of the present application.

It should be noted that, in this article, relational terms such as first and second, etc. are only used to distinguish one entity or operation from another entity or operation, and do not necessarily require or imply any such actual relationship or order between these entities or operations. Moreover, the terms “comprise”, “comprise” or any other variants thereof are intended to cover non-exclusive inclusion, so that a process, method, article or apparatus comprising a series of elements comprises not only those elements, but also other elements not explicitly listed, or also comprises elements inherent to such process, method, article or apparatus. In the absence of further restrictions, the elements defined by the statement “comprise . . . ” do not exclude the existence of other identical elements in the process, method, article or apparatus comprising the elements.

The applicant has discovered that in the related art, the process performance of existing OLED display panels needs to be improved.

In view of the above problems, the applicant proposes a display panel, comprising a base plate, a plurality of first electrodes distributed in an array on a side of the base plate and having first edge areas, and an isolation structure. The isolation structure is provided on a side of the base plate, located on the same side of the base plate as the first electrodes, and encloses a plurality of isolation openings. The isolation structure and the first electrodes are insulated from each other and at least part of the first electrodes are exposed from the isolation openings. In the thickness direction of the display panel, the isolation structure comprises isolation walls comprising first surfaces away from the base plate, second surfaces facing the base plate and first side surfaces connecting the first surfaces and the second surfaces, and orthographic projections of at least part of the first edge areas on the base plate are staggered with orthographic projections of the first side surfaces on the base plate.

In the display panel of the embodiment of the present application, the display panel comprises a base plate, a plurality of first electrode distributed on a side of the base plate and used to drive the plurality of light-emitting functional portions of the display panel to emit light for display, and an isolation structure. The first electrodes have first edge areas, which will affect the flatness of the subsequent film layer away from the base plate surface. The isolation structure are provided on the same side of the base plate as the first electrodes and encloses to form isolation openings, and at least part of the first electrodes are exposed from the isolation openings, so that the isolation openings can be used to accommodate the light-emitting functional portions, and the first electrodes exposed from the isolation openings can drive the light-emitting functional portions in the isolation openings to emit light. The isolation structure comprises isolation walls comprising first side surfaces, orthographic projections of at least part of the first edge areas on the base plate are staggered with orthographic projections of the first side surfaces on the base plate, so that at least part of the first edge areas will not affect the flatness of the first side surfaces, which is convenient for the subsequent film layers to overlap on the first side surfaces, thereby improving the process performance of the display panel.

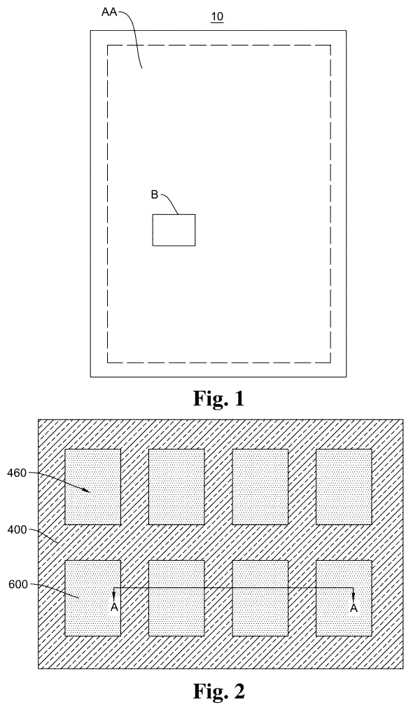

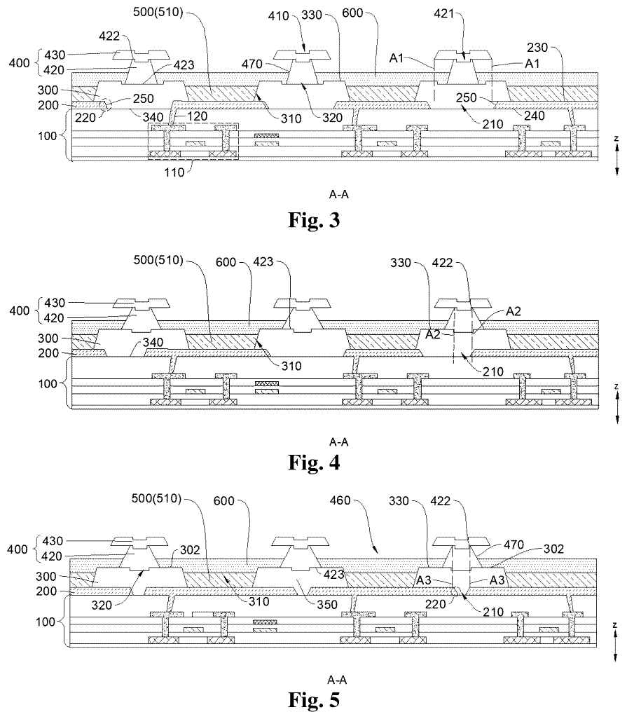

In order to better understand the present application, the display panel and display apparatus of embodiments of the present application are described in detail below in conjunction with the accompanying drawings. It is noted that direction z in the accompanying drawings is the thickness direction of the display panel. In the accompanying drawings, for the convenience of drawing, the dimensions in the drawings are not necessarily proportional to the actual dimensions, and some hierarchical structures in the display module are not drawn. Please refer to FIGS. 1 to 3, FIG. 1 is a top view structural schematic diagram of a display panel 10 in some embodiments of the present application; FIG. 2 shows an enlarged top view structural schematic diagram of the display panel in area B in FIG. 1; FIG. 3 shows an exemplary cross-sectional view of the display panel in FIG. 2 along section AA. The area B in FIG. 1 is located in the display area AA of the display panel 10.

As shown in FIGS. 1 to 3, an embodiment of a first aspect of the present application provides a display panel 10, which comprises a base plate 100, a plurality of first electrodes 200 distributed in an array on a side of the base plate 100 and having first edge areas 220, and an isolation structure 400 located on a same side of the base plate 100 as the first electrodes 200, enclosing a plurality of isolation openings 460 and insulated from the first electrodes 200, from which at least part of the first electrode 200 is exposed; wherein, the isolation structure 400 comprises isolation walls 420, which comprises first surfaces 422 away from the base plate 100, second surfaces 423 facing the base plate 100 in the thickness direction Z of the display panel 10, as well as first side surfaces 470 connecting the first surfaces 422 and the second surfaces 423, and orthographic projections of at least part of the first edge areas 220 on the base plate 100 are staggered with orthographic projections of the first side surfaces 470 on the base plate 100.

In the display panel 10 of the embodiment of the present application, the display panel 10 comprises a base plate 100, a plurality of first electrodes 200 distributed in an array on a side of the base plate 100 and configured to drive a plurality of light-emitting functional portions 510 of the display panel 10 to emit light for display, and an isolation structure 400. The first electrodes 200 have first edge areas 220, which affects the flatness of the subsequent film layer away from the surface of the base plate 100. The isolation structure 400 is provided on the same side of the base plate 100 as the first electrodes 200 and encloses isolation openings 460, from which at least part of the first electrode 200 is exposed, so that the isolation openings 460 can be used to accommodate the light-emitting functional portions 510. The first electrodes 200 exposed from the isolation openings 460 can drive the light-emitting functional portions 510 in the isolation openings 460 to emit light. The isolation structure 400 comprises isolation walls 420 comprising first side surfaces 470. The orthographic projections of at least part of the first edge areas 220 on the base plate 100 are staggered with the orthographic projections of the first side surfaces 470 on the base plate 100, so that at least part of the first edge areas 220 will not affect the flatness of the first side surfaces 470, which facilitates the subsequent film layer to be overlapped on the first side surface 470, thereby improving the process performance of the display panel 10.

In some optional embodiments, the base plate 100 may further comprise a base plate and circuit layers, which may comprise pixel circuits. For example, the circuit layers may comprise a first conductive layer, a second conductive layer, and a third conductive layer that are provided on a side of the base plate and are stacked. An inorganic layer or an organic layer is provided between adjacent conductive layers for insulation. Exemplarily, the pixel circuits provided in the circuit layers comprise transistors and storage capacitors. The transistors comprises semiconductors, gates, sources and drains. The storage capacitors comprise first plates and second plates. As an example, the gates and the first plates may be located in the first conductive layer, the second plates may be located in the second conductive layer, and the sources and the drains may be located in the third conductive layer.

Optionally, as shown in FIG. 3, the first electrodes 200 have first bottom surfaces 240 facing the base plate 100, first top surfaces 230 away from the base plate 100, and first side walls 250 connecting the first top surfaces 230 and the first bottom surfaces 240. When the first top surfaces 230 have the same sizes as the first bottom surfaces 240 and the first side walls 250 extend along the thickness direction Z, the first edge areas 220 may be edges of the first top surfaces 230 and/or the first bottom surfaces 240. When the first top surfaces 230 have different sizes as the first bottom surfaces 240 and the first side walls 250 are inclined relative to the thickness direction Z, the areas where the first side walls 250 are located may be considered as the first edge areas 220, and the orthographic projections of the first side walls 250 on the base plate 100 may be considered as the orthographic projections of the first edge areas 220 on the base plate 100.

Optionally, the first electrodes 200 further comprise first central areas, which are surround by the first edge areas 220. Optionally, areas of the first electrodes 200 other than the first edge areas 220 may be the first central areas. At least part of the orthographic projections of the first edge areas 220 on the base plate 100 are staggered with the orthographic projections of the first side surfaces 470 on the base plate 100, that is, the orthographic projections of the first edge areas 220 on sides of the first central areas may be staggered with the orthographic projections of the first side surfaces 470 on the base plate 100, or the orthographic projections of the first edge areas 220 on the central peripheral sides of the first areas may be staggered with the orthographic projections of the first side surfaces 470 on the base plate 100, as long as at least part of the orthographic projections of the first edge areas 220 on the base plate 100 are staggered with the orthographic projections of the first side surfaces 470 on the base plate 100.

In some optional embodiments, the display panel 10 further comprises a light-emitting functional layer 500 comprising a plurality of light-emitting functional portions 510 at least partially located in the isolation openings 460, and second electrodes 600. The second electrodes 600 are located on a side of the light-emitting functional layer 500 away from the base plate 100. The first electrodes 200 and the second electrodes 600 are electrically connected with the light-emitting functional portions 510 and are used to provide power to the light-emitting functional portions 510 to drive the light-emitting functional portions 510 to emit light. Specifically, one of a first electrode 200 and a second electrode 600 is an anode, and the other one is a cathode. The embodiment of the present application is illustrated by taking the second electrode 600 as a cathode and the first electrode 200 as an anode.

The light-emitting functional layer 500 may comprise film layer structures comprising a hole injection layer (HIL), a hole transport layer (HTL), a light-emitting material layer (EL), an electron transport layer (ETL), and an electron injection layer (EIL) stacked in sequence. The light-emitting material layer (EL) may comprise a light-emitting material for a red sub-pixel, a light-emitting material for a green sub-pixel, and a light-emitting material for a blue sub-pixel.

Optionally, the isolation structure 400 is located between light-emitting functional portions 510 adjacent to it.

Optionally, the isolation walls 420 comprise a conductive material, and the second electrodes 600 are electrically connected with the isolation walls 420. Optionally, the second electrodes 600 are overlapped on the first side surfaces 470, and the isolation walls 420 provide a power signal for the second electrodes 600.

In the display panel 10 provided in the embodiment of the present application, since at least part of the orthographic projections of the first edge areas 220 on the base plate 100 are staggered with the orthographic projections of the first side surfaces 470 on the base plate 100, at least part of the first edge areas 220 will not affect the flatness of the first side surfaces 470, thereby facilitating the overlap of the second electrodes 600 with the first side surfaces 470, thereby improving the connection yield between the second electrodes 600 and the isolation walls 420, and improving the process performance of the display panel 10.

In some embodiments, the isolation structure 400 can not only isolate the light-emitting functional layer 500, but also isolate the second electrode layer, thereby forming the second electrodes 600.

Optionally, the second electrodes 600 are separated by the isolation structure 400, and a plurality of second electrodes 600 can be electrically connected via other components. For example, the second electrodes 600 are in contact with the isolation structure 400, via which the second electrodes 600 in at least two adjacent pixel openings 310 are electrically connected.

The isolation structure 400 has a conductive material, via which the second electrodes 600 in at least two adjacent isolation openings 460 are electrically connected. Since the isolation structure 400 has good dimensional uniformity in the above embodiment, the second electrodes 600 can be easily overlapped to the conductive material of the isolation structure 400, so as to realize the electrical connection of adjacent second electrodes 600 via the conductive material of the isolation structure 400.

For example, the second electrodes 600 in at least two adjacent isolation openings 460 are electrically connected via the isolation walls 420. The isolation structure 400 has good dimensional uniformity, so the second electrodes 600 can be easily overlapped to the isolation walls 420.

In the display panel 10 provided in this embodiment, the second electrodes 600 corresponding to at least two adjacent pixel openings 310 are electrically connected via the isolation structure 400, so that the display panel 10 can achieve regional connection or full surface connection.

Please continue to refer to FIGS. 2 and 5, in some optional embodiments, the orthographic projection of the isolation structure 400 on the base plate 100 is in a grid shape. The isolation structure 400 can isolate the light-emitting functional portions 510, for example, the isolation structure 400 can isolate the light-emitting functional portions 510 of each sub-pixel. The isolation structure 400 can isolate the light-emitting functional portions 510 of a group of sub-pixels, for example, the isolation structure 400 can isolate the light-emitting functional portions 510 of a group of sub-pixels of the same color.

Optionally, please continue to refer to FIGS. 1 to 3, the display panel 10 further comprises first insulating layers 300, provided on sides of the first electrodes 200 away from the base plate 100 and comprising pixel defining portions 350 and pixel openings 310 formed by the pixel defining portions 350, orthographic projections of the pixel openings 310 on the base plate 100 at least partially overlaps with the orthographic projections of the first electrodes 200 on the base plate 100, so that the first electrodes 200 can be exposed from the pixel openings 310. Optionally, the isolation structure 400 is located on sides of the first insulating layers 300 away from the base plate 100, and the isolation openings 460 are connected with the pixel openings 310, so that the first electrodes 200 can be exposed from the isolation openings 460 and the pixel openings 310.

In these optional embodiments, the first edge areas 220 may affect the flatness of the surfaces of the first insulating layers 300, which may affect the flatness of the isolation structure 400 provided thereon. By the orthographic projections of at least part of the first edge areas 220 on the base plate 100 staggering with the orthographic projections of the first side surfaces 470 on the base plate 100, at least part of the first edge areas 220 will not affect the flatness of the first insulating layers 300 below the first side surfaces 470, and further will not affect the flatness of the first side surfaces 470, so that the second electrodes 600 are easily overlapped with the first side surfaces 470, and the connection yield of the second electrodes 600 and the isolation walls 420 can be improved, thereby improving the process performance of the display panel.

As shown in FIGS. 1 to 4, there are many ways to set the first surfaces 422 and the second surfaces 423, for example, the first surfaces 422 and the second surfaces 423 have same sizes. In other optional embodiments, the first surfaces 422 and the second surfaces 423 have different orthographic projection areas on the base plate 100, so that the first side surfaces 470 are tilted, which is more convenient for overlapping the second electrodes 600.

In some optional embodiments, at least part of the orthographic projections of the first edge areas 220 on the base plate 100 are located within the orthographic projections of the first surfaces 422 or the second surfaces 423 on the base plate 100 having smaller orthographic projection areas on the base plate 100.

In these optional embodiments, the first edge areas 220 can extend to the smaller ones of the first surfaces 422 and the second surfaces 423, that is, the first edge areas 220 can extend to under the isolation walls 420, so that the first edge areas 220 are staggered with the first side surfaces 470, and may not affect the flatness of the first side surfaces 470.

Optionally, as shown in FIG. 5, when the orthographic projections of the first surfaces 422 on the base plate 100 are located within the orthographic projections of the second surfaces 423 on the base plate 100, at least part of the orthographic projections of the first edge areas 220 on the base plate 100 are located within the orthographic projections of the first surfaces 422 on the base plate 100, that is, when the sizes of the first surfaces 422 are smaller and the area sizes of the second surfaces 423 are larger, at least part of the first edge areas 220 are located below the first surfaces 422, and at least part of the first edge areas 220 extend below the first surfaces 422 to be staggered with the first side surfaces 470.

The dotted line A3 in FIG. 5 does not refer to physical connection lines, but projection lines of the orthographic projections of the first surfaces 422 on the base plate 100. The orthographic projections of the first surfaces 422 on the base plate 100 can be understood as the interval between the two dotted lines A3 in FIG. 5. The orthographic projections of the first electrodes 200 on the base plate 100 at least partially overlap with the orthographic projections of the first surfaces 422 on the base plate 100, that is, the orthographic projections of the first gaps 210 on the base plate 100 are located within the orthographic projections of the first surfaces 422 on the base plate 100, which can reduce the undulating area of the first insulating layers 300, improve the size uniformity of the isolation structure 400, and further improve the display effect of the display panel 10.

Optionally, in the direction away from the base plate 100, the first side surfaces 470 are inclined toward the direction away from the isolation openings 460. When the isolation structure 400 is provided on the sides of the first insulating layers 300 away from the base plate 100, angles between the first side surfaces 470 and the surfaces of the first insulating layers 300 exposed by the isolation openings 460 are greater than 90 degrees, so that the second electrodes 600 are overlapped on the first side surfaces 470.

In some optional embodiments, the orthographic projections of the first edge areas 220 on the base plate 100 are located within the orthographic projection of the first surface 422 on the base plate 100, or part of the orthographic projections of the first edge areas 220 on the base plate 100 are located within the orthographic projections of the first surfaces 422 on the base plate 100, and the other part of the orthographic projections of the first edge areas 220 on the base plate 100 are staggered with the orthographic projections of the second surfaces 423 on the base plate 100. That is, as shown in FIG. 5, the entire first edge areas 220 extend below the first surfaces 422, or, as shown in FIG. 4, part of the first edge areas 220 extend below the first surfaces 422, and part of the first edge areas 220 extend outside the second surfaces 423 and are staggered with the isolation walls 420, as long as the orthographic projections of the first edge areas 220 on the base plate 100 are staggered with the orthographic projections of the first side surfaces 470 on the base plate 100.

The dotted line A2 in FIG. 4 does not refer to physical connection lines, but projection lines of the orthographic projections of the first surfaces 422 on the base plate 100. The orthographic projections of the first surfaces 422 on the base plate 100 can be understood as the intervals between the two dotted lines A2 in FIG. 4. Part of the first edge areas 220 extend below the first surfaces 422, and part of the first edge areas 220 extend outside the second surfaces 423 and are staggered with the isolation walls 420.

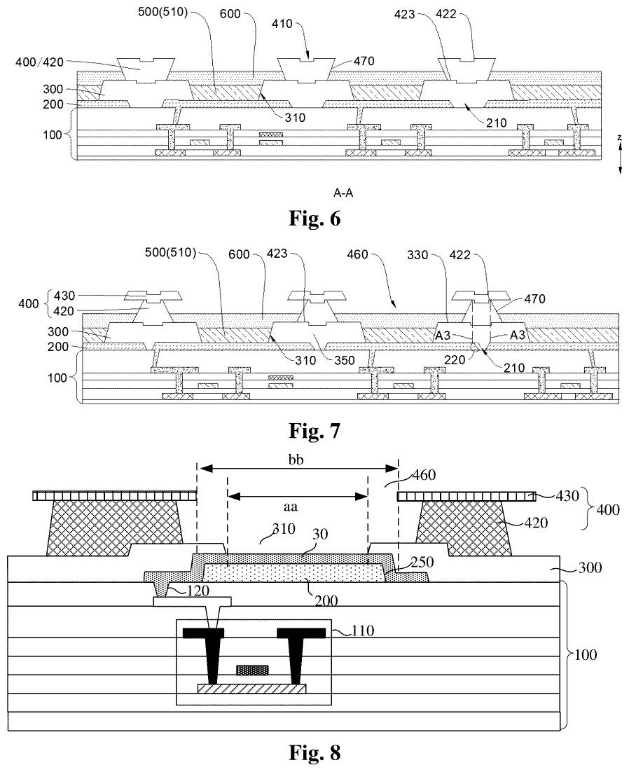

In some other optional embodiments, as shown in FIG. 6, the orthographic projections of the second surfaces 423 on the base plate 100 are located within the orthographic projections of the first surfaces 422 on the base plate 100; at least part of the orthographic projections of the first edge areas 220 on the base plate 100 are located within the range of the orthographic projections of the second surfaces 423 on the base plate 100.

In these optional embodiments, the area sizes of the second surfaces 423 are smaller, the area sizes of the first surfaces 422 are larger, at least part of the orthographic projection of the first edge areas 220 on the base plate 100 are located within the range of the orthographic projections of the second surfaces 423 on the base plate 100, so that at least part of the first edge areas 220 extend below the second surfaces 423 with smaller areas.

Optionally, in the direction away from the base plate 100, the first side surfaces 470 are inclined toward the direction close to the isolation openings 460, so that concaves can be formed under the first side surfaces 470, which facilitates light-emitting materials to be disconnected here to form independent light-emitting functional portions 510.

Optionally, first gaps 210 are formed between first electrodes 200 adjacent to them. As shown in FIG. 6, optionally, the orthographic projections of the first gaps 210 on the base plate 100 are located within the orthographic projections of the second surfaces 423 of the isolation walls 420 on the base plate 100.

In some optional embodiments, as shown in FIGS. 1 to 6, as described above, the display panel 10 further comprises first insulating layers 300 filled between adjacent first electrodes 200. The isolation structure 400 is provided on sides of the first insulating layers 300 away from the base plate 100 which provided with first recesses 320, the orthographic projections of which on the base plate 100 are staggered with the orthographic projections of the first electrodes 200 on the base plate 100. In these embodiments, due to the presence of the first electrodes 200, the surfaces of the first insulating layers 300 away from the base plate 100 are uneven, and the insulating layers fill the first gaps 210 between adjacent first electrodes 200 to form the first recesses 320.

Optionally, as shown in FIG. 6, the orthographic projections of the first electrodes 200 on the base plate 100 at least partially overlap with the orthographic projections of the second surfaces 423 on the base plate 100. By the orthographic projections of the first electrodes 200 on the base plate 100 at least partially overlapping with the orthographic projections of the second surfaces 423 on the base plate 100, that is, the orthographic projections of the first gaps 210 on the base plate 100 being located within the orthographic projections of the second surfaces 423 on the base plate 100, the boundaries of the first electrodes 200 extend into the coverage of the isolation walls 420, so that the first gaps 210 are reduced, the undulating areas of the first insulating layers 300 will be further reduced, and the uniformity of the size of the isolation structure 400 (such as the height of the isolation structure 400) is improved, thereby improving the display effect of the display panel 10.

Optionally, at least part of the orthographic projections of the first edge areas 220 on the base plate 100 are located within the orthographic projections of the first surfaces 422 or the second surfaces 423 with smaller orthographic projection areas on the base plate 100 on the base plate 100. Then, the orthographic projections of the first recesses 320 on the base plate 100 are located within the orthographic projections of the first surfaces 422 or the second surfaces 423 with smaller areas on the base plate 100, and part of the isolation walls 420 are located in the first recess 320.

In these optional embodiments, as shown in FIG. 5 or FIG. 6, due to the presence of the first electrodes 200, first recesses 320 are formed on the first insulating layers 300, in which part of the isolation walls 420 are located, that is, the isolation walls 420 completely cover the first recesses 320, which can increase the contact areas of the isolation walls 420 and the first insulating layers 300 and improve the connection yield of the isolation walls 420 and the first insulating layers 300. In some optional embodiments, the orthographic projections of the first recesses 320 on the base plate 100 at least partially overlap with the orthographic projections of the first gaps 210 on the base plate 100, and at least part of the isolation structure 400 is located in the first recesses 320.

Optionally, at least part of the first insulating layers 300 are located in the first gaps 210, so that the first recesses 320 are formed on sides of the first insulating layers 300 away from the base plate 100.

Optionally, the first insulating layers 300 comprise fifth surfaces 330 which are upper surfaces of the first insulating layers 300 away from the base plate 100, and sixth surfaces 340 which are lower surfaces of the first insulating layers 300 facing the base plate 100. The orthographic projections of the fifth surfaces 330 on the base plate 100 are located within the orthographic projections of the sixth surfaces 340 on the base plate 100, and the orthographic projections of the first gaps 210 on the base plate 100 are located within the orthographic projections of the fifth surfaces 330 on the base plate 100.

In the display panel 10 provided in the embodiment of the present application, the orthographic projections of the first gaps 210 on the base plate 100 are located within the orthographic projections of the fifth surfaces 330 on the base plate 100, that is, the boundaries of the first electrodes 200 extend into the coverage ranges of the fifth surfaces 330, so that the boundaries of the first electrodes 200 are staggered with the boundaries of the first insulating layers 300 which refer to the junction of the fifth surfaces 330 and the side surfaces of the first insulating layers 300, thereby reducing the undulating areas of the first insulating layers 300, which is beneficial to manufacture the isolation structure 400 in the subsequent process and improve the process performance of the display panel 10.

Optionally, at least part of the isolation walls 420 are located in the first recesses 320, sides of the isolation walls 420 away from the base plate 100 are provided with third recesses 421, orthographic projections of which on the base plate 100 at least partially overlap with the orthographic projections of the first recesses 320 on the base plate 100, and/or at least partially staggered with the orthographic projections of the first electrodes 200 on the base plate 100.

In some optional embodiments, as shown in FIG. 6, the isolation structure 400 may only comprise isolation walls 420, which comprise first surfaces 422 that are upper surfaces of the isolation structure 400 away from the base plate 100 and second surfaces 423 that are lower surfaces of the isolation structure 400 facing the base plate 100. The orthographic projections of the second surfaces 423 on the base plate 100 are located within the orthographic projections of the first surfaces 422 on the base plate 100, and the orthographic projections of the first electrodes 200 on the base plate 100 at least partially overlap with the orthographic projections of the second surfaces 423 on the base plate 100.

Optionally, the orthographic projections of the first gaps 210 on the base plate 100 are located within the orthographic projections of the second surfaces 423 on the base plate 100, so that the boundaries of the first electrodes 200 extend to the coverage range of the isolation structure 400, reducing the undulating areas of the first insulating layers, which is beneficial to improving the process performance of the display panel 10.

Optionally, the section of the isolation structure 400 in the thickness direction Z (direction z in the figure) of the display panel 10 is an inverted trapezoid. By setting the section of the isolation structure 400 in the thickness direction Z of the display panel 10 an inverted trapezoid, the apparatuses are independent of each other, the optical performance of the display panel 10 is optimized, and the independent packaging of each light-emitting functional unit 510 is achieved, thereby improving the packaging reliability of the display panel 10.

Optionally, the isolation structure 400 is an integrated structure, and is formed into an inverted trapezoidal structure by etching. The second recesses 410 are located on the first surfaces 422.

Optionally, in other optional embodiments, as shown in FIGS. 1 to 5, the isolation structure 400 further comprises barrier parts 430 provided on the sides of the isolations wall 420 away from the base plate 100, the orthographic projections of the isolation walls 420 on the base plate 100 are located within orthographic projections of the barrier parts 430 on the base plate 100, at least part of the barrier parts 430 are located in the third recesses 421, the second recesses 410 are located on sides of the barrier parts 430 away from the isolation walls 420, and the orthographic projections of the second recesses 410 on the base plate 100 at least partially overlap with the orthographic projections of the third recesses 421 on the base plate 100.

As shown in FIG. 3, in some optional embodiments, the orthographic projections of the isolation walls 420 on the base plate 100 are located within the orthographic projections of the barrier parts 430 on the base plate 100, and the orthographic projections of the first gaps 210 on the base plate 100 are located within the orthographic projections of the barrier parts 430 on the base plate 100. The dotted line A1 in FIG. 3 does not refer to physical connection lines, but projection lines of the orthographic projections of the barrier parts 430 on the base plate 100. The orthographic projections of the barrier parts 430 on the base plate 100 can be understood as the intervals between the two dotted lines A1 in FIG. 3.

In some optional embodiments, as shown in FIGS. 1 to 6, a side of the isolation structure 400 away from the base plate 100 is provided with second recesses 410, orthographic projections of which on the base plate 100 at least partially overlap with the orthographic projections of the first recesses 320 on the base plate 100.

Optionally, orthographic projections of the second recesses 410 on the base plate 100 at least partially overlap with orthographic projections of the first gaps 210 on the base plate 100.

In the display panel 10 provided in the embodiment of the present application, at least part of the first insulating layers 300 are located in the first gaps 210, so that the first insulating layers 300 form first recesses 320 on the sides away from the base plate 100, and at least part of the isolation structure 400 is located in the first recesses 320, so that the side of the isolation structure 400 away from the base plate 100 form the second recesses 410.

The isolation structure 400 can replace the metal mask, thereby reducing the mold opening cost and improving the pixel density of the display panel 10. By the barrier part 430 forming into a roof-like structure, while the apparatuses being independent of each other, the optical performance of the display panel 10 is optimized. The orthographic projections of the first gaps 210 on the base plate 100 are located within the orthographic projections of the barrier parts 430 on the base plate 100. For example, the barrier parts 430 each have two surfaces opposite to each other in the thickness direction Z, the orthographic projections of the first gaps 210 on the base plate 100 are located within the orthographic projections of the smaller one of the two surfaces on the base plate 100, that is, the boundaries of the first electrodes 200 extend into the coverage ranges of the barrier parts 430, reducing the undulating areas of the first insulating layers 300, thereby reducing the undulation of the film layer forming the isolation structure 400 in a larger area, which is conducive to manufacturing the isolation structure 400 in the subsequent process and improving the process performance of the display panel 10.

In some optional embodiments, the isolation wall 420 and the barrier parts 430 both comprise metal materials, furthermore, the isolation wall 420 and the barrier parts 430 comprise different metal materials. For example, the isolation wall 420 comprises aluminum, and the barrier parts 430 comprise titanium. Of course, the materials of the isolation wall 420 and the barrier parts 430 are not limited thereto, and may also comprise other types of metal materials, which are not specifically limited here. For better explanation, the following takes the isolation wall 420 comprising aluminum and the barrier parts 430 comprising titanium as an example to illustrate the embodiments of the present application.

After forming the metal aluminum layers of the isolation walls 420 and the metal titanium layers of the barrier parts 430 and before forming the isolation walls 420 and the barrier parts 430, the metal aluminum layers and the metal titanium layers may be dry-etched first and then wet-etched to form the isolation structure 400 with a larger top and smaller bottom. By designing the boundaries of the first electrodes 200 to extend to the coverage ranges of the barrier parts 430, the influence of the fluctuation of the metal aluminum layers and the metal titanium layers on the dry etching may be reduced, thereby improving the dry etching effect.

Optionally, the orthographic projections of the third recesses 421 on the base plate 100 at least partially overlap with the orthographic projections of the first gaps 210 on the base plate 100. Optionally, the orthographic projections of the third recesses 421 on the base plate 100 are at least partially staggered with the orthographic projections of the first electrodes 200 on the base plate 100.

In the display panel 10 provided in the embodiment of the present application, at least part of the first insulating layers 300 are located in the first gaps 210, so that the sides of the first insulating layers 300 away from the base plate 100 form first recesses 320, in which at least part of the isolation walls 420 are located, so that the sides of the isolation walls 420 away from the base plate 100 form third recesses 421, in which at least part of the barrier parts 430 are located, so that the sides of the barrier parts 430 away from the base plate 100 form second recesses 410.

In some other optional embodiments, as shown in FIG. 3, at least part of the orthographic projections of the first edge areas 220 on the base plate 100 are staggered with the orthographic projections of the isolation walls 420 on the base plate 100. FIG. 3 illustrates the boundary of one of the first edges with a dotted line.

In these optional embodiments, the distribution areas of the first electrodes 200 are smaller, and at least part of the first edge areas 220 do not extend below the isolation walls 420 to improve the effect of the first edge areas 220 on the flatness of the isolation walls 420.

Optionally, the orthographic projections of the first edge areas 220 on the base plate 100 are staggered with the orthographic projections of the isolation walls 420 on the base plate 100, that is, the first electrodes 200 do not extend below the isolation walls 420 at all, and the first electrodes 200 do not affect the flatness of the isolation walls 420 at all.

Optionally, as shown in FIG. 3, the orthographic projections of the first electrodes 200 on the base plate 100 are located within the orthographic projections of the isolation openings 460 on the base plate 100, so that the first electrodes 200 can drive the light-emitting functional portions 510 in the isolation openings 460 to emit light for display.

As described above, the display panel 10 further comprises first insulating layers 300, the isolation structure 400 is provided on sides of the first insulating layers 300 away from the base plate 100. Optionally, sides of the first insulating layers 300 away from the base plate 100 are provided with first recesses 320, the orthographic projections of which on the base plate 100 are staggered with the orthographic projections of the first electrodes 200 on the base plate 100.

Optionally, the orthographic projections of the isolation walls 420 between adjacent sub-pixels on the base plate 100 are located within the orthographic projections of the first recesses 320 on the base plate 100.

In these optional embodiments, due to the presence of the gaps between adjacent first electrodes 200, the first recesses 320 are formed on the insulating layers, the orthographic projections of the isolation walls 420 on the base plate 100 are located within the orthographic projections of the first recesses 320 on the base plate 100, so that the edges of the first recesses 320 are unlikely to affect the flatness of the first side surfaces of the isolation walls 420.

In some optional embodiments, as shown in FIG. 3, the base plate 100 comprises pixel circuits 110 and first via holes 120 between the pixel circuits 110 and the first electrodes 200. The pixel circuits 110 are electrically connected with the first electrodes 200 via the first via holes 120. Orthographic projections of the first via holes 120 on the plane where the base plate 100 is located are staggered with the orthographic projections of the isolation walls 420 on the plane where the base plate 100 is located, which improves the flatness of the isolation walls 420 affected by the presence of the first via holes 120 and improves the overlap yield of the second electrodes 600 and the isolation walls 420.

In some optional embodiments, as shown in FIG. 7, in the thickness direction Z of the base plate 100, the base plate 100 comprises pixel circuits 110 and first via holes 120 located between the pixel circuits 110 and the first electrodes 200, the orthographic projections of the first via holes 120 on the plane where the base plate 100 is located are located within the ranges of the orthographic projections of the isolation walls 420 on the plane where the base plate 100 is located, and the orthographic projections of the first via holes 120 on the base plate 100 are staggered with the orthographic projections of the first side surfaces 470 on the base plate 100. This makes it difficult for the first via holes 120 to affect the flatness of the first side surfaces 470, so as to improve the overlap yield of the second electrodes 600 and the first side surfaces 470.

In some optional embodiments, as shown in FIG. 8, the display panel 10 further comprises auxiliary electrodes 30 electrically connected with the first electrodes 200 and used to provide electrical signals to the first electrodes 200. For example, the auxiliary electrodes 30 are electrically connected with the pixel circuits 110 via the first via holes 120. In this embodiment, the auxiliary electrodes 30 are provided, while the auxiliary electrodes 30 are overlapped with the first electrodes 200, so that the voltage signal is transmitted to the first electrodes 200 via the auxiliary electrodes 30.

Optionally, as shown in FIGS. 8 to 10, the auxiliary electrodes 30 are located on the sides of the first electrodes 200 away from the base plate 100. The auxiliary electrodes 30 cover the first electrodes 200, which can protect the first electrode 200 from being damaged by the manufacturing process of the auxiliary electrode 30, thereby improving the integrity of the first electrode 200.

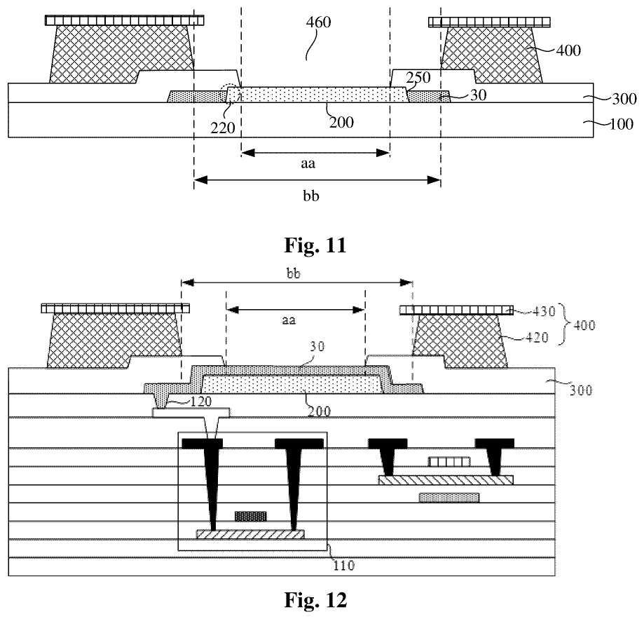

Optionally, as shown in FIG. 11, the auxiliary electrodes 30 are in contact with the outer peripheral surfaces of the first electrodes 200, for example, the auxiliary electrodes 30 are in contact with the first side walls 250, that is, the auxiliary electrodes 30 do not cover the first top surfaces 230 and in contact with the first side walls 250, improving the flatness of the film layer affected by setting the auxiliary electrodes 30.

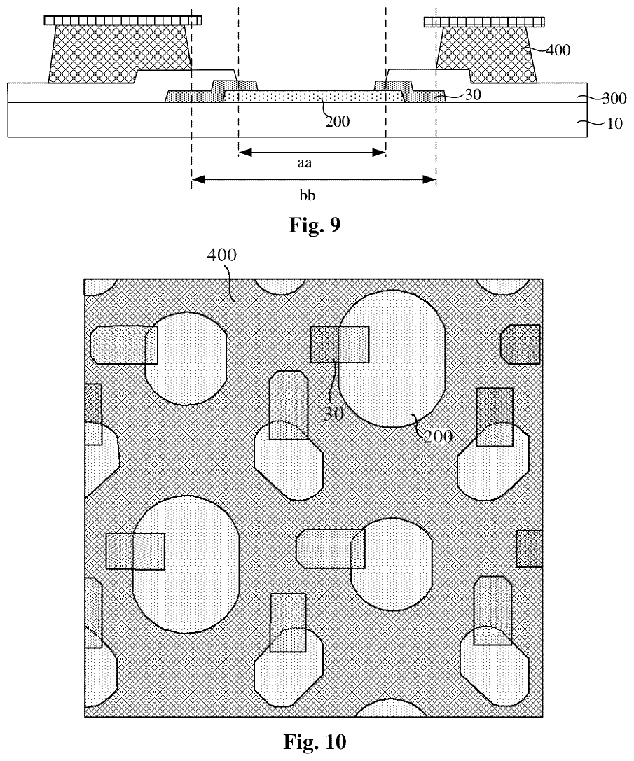

Optionally, as shown in FIG. 8, the orthographic projections of the auxiliary electrodes 30 on the base plate 100 cover the orthographic projections of the first electrodes 200 on the base plate 100. The auxiliary electrodes 30 can be exposed from the isolation openings 460. This configuration can reduce the number of masks and the number of etching times, thereby simplifying the process. Alternatively, as shown in FIGS. 9 and 10, the auxiliary electrodes 30 can cover part of the first electrodes 200 to reduce the distribution areas of the auxiliary electrodes 30 and improve the excessive height difference of the film layer caused by setting the auxiliary electrode 30.

Optionally, as shown in FIGS. 8 and 12, the orthographic projections of the auxiliary electrodes 30 on the base plate 100 partially overlap with the orthographic projections of the isolation walls 420 on the base plate 100 and cover the first via holes 120. The auxiliary electrodes 30 can extend below the isolation structure 400 and be electrically connected with the pixel circuits 110 via the first via holes 120 below the isolation structure 400.

Optionally, in the thickness direction Z of the display panel 10, the thickness of the auxiliary electrodes 30 each are less than the thickness of the first electrodes 200. When the auxiliary electrodes 30 are connected with the pixel circuits 110, even if the auxiliary electrodes 30 are located below the isolation structure 400, the auxiliary electrodes 30 have little effect on the flatness of the upper surfaces of the insulating layers since the thickness of the auxiliary electrodes 30 each are less than the thickness of the first electrodes 200, compared with the solution of the prior art, the flatness of the isolation structure 400 can be improved.

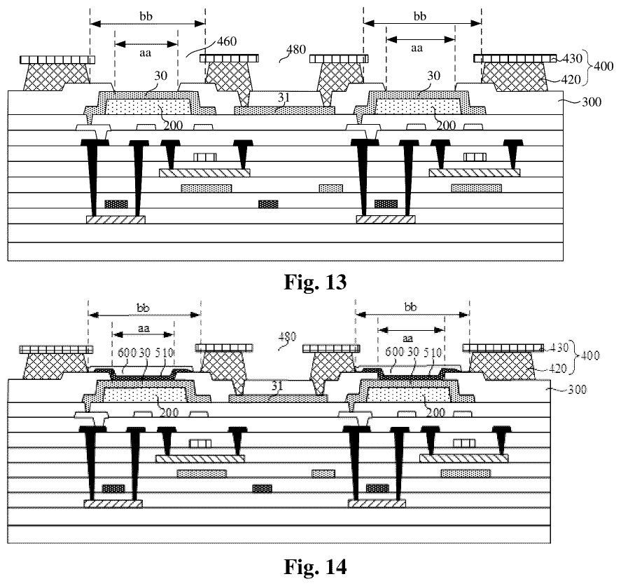

Optionally, as shown in FIGS. 13 to 15, the isolation structure 400 is provided with light transmitting holes 480 arranged at intervals from the isolation openings 460, the display panel 10 further comprises transparent conductive connection portions 31 provided in the same layer as the auxiliary electrodes 30, the isolation structure 400 surrounding the light transmitting holes 480 is connected with the transparent conductive connection portions 31. Optionally, the isolation structure 400 comprises conductive material, which can provide voltages to the transparent conductive connection portions 31, so that the transparent conductive connection portions 31 play shielding roles, preventing the touch signals of the upper layers from interfering with the driving signals of the lower layers which would cause problems such as poor touch or display. Optionally, the transparent conductive connection portions 31 are provided in the same layer as the auxiliary electrodes 30 and are provided at intervals from the auxiliary electrodes 30 to reduce the number of film layers, which is conducive to reducing the thickness of the display panel 10. In which the materials of the transparent conductive connection portions 31 and the auxiliary electrodes 30 both comprise indium tin oxide.

Optionally, the transparent conductive connection portions 31 are spaced apart from the auxiliary electrodes 30, and the orthographic projections of the transparent conductive connection portions 31 on the base plate 100 cover the orthographic projections of the light transmitting holes 480 on the base plate 100, so as to improve the shielding effect of the transparent conductive connection portions 31.

Optionally, the first electrodes 200 and the transparent conductive connecting portions 31 are provided at intervals to improve the short circuit connection between the first electrodes 200 and the transparent conductive portions 270, thereby improving the short circuit connection between the first electrodes 200 and the isolation structure 400.

Optionally, the thickness of the auxiliary electrodes 30 each are 0.01 μm-0.1 μm, so as to improve the problem that the thickness of the auxiliary electrodes 30 are too large and affect the flatness of the film layer, and also improve the problem that the thickness of the auxiliary electrodes 30 are too small and affects the connection between the first electrodes 200 and the pixel circuits 110.

Optionally, the isolation structure 400 further comprises barrier parts 430 provided on the sides of the isolation walls 420 away from the base plate 100, the orthographic projections of the isolation walls 420 on the base plate 100 are located within the orthographic projections of the barrier parts 430 on the base plate 100. This allows concaves to be formed under the barrier parts 430, making it easier for the luminescent material to be broken into mutually independent light-emitting functional portions 510 at this point, thereby simplifying the preparation of the display surface.

Optionally, as shown in FIG. 9, at least part of the orthographic projections of the first edge areas 220 on the base plate 100 are staggered with the orthographic projection of the isolation structure 400 on the base plate 100. That is, at least part of the first edge areas 220 do not extend below the isolation structure 400. Optionally, the orthographic projections of the first edge areas 220 on the base plate 100 are, for example, located within the orthographic projections of the isolation openings 460 on the base plate 100, and staggered with the orthographic projection of the isolation structure 400 on the base plate 100.

Optionally, the display panel 10 further comprises first insulating layers 300 located on a side of the base plate 100, the isolation structure 400 is located on sides of the first insulating layers 300 away from the base plate 100. The first insulating layers 300 comprise pixel defining portions 350 and pixel openings 310 formed by the pixel defining portions 350, orthographic projections of the pixel openings 310 on the base plate 100 at least partially overlap with the orthographic projection of the first electrodes 200 on the base plate 100, so that the first electrodes 200 can be electrically connected with the light-emitting functional portions 510 in the pixel openings 310. The aa areas in FIG. 8 are the areas where the pixel openings 310 are located. The bb areas are the areas where the isolation openings 460 are located.

Optionally, the width of parts of the pixel defining portions between two pixel openings 310 adjacent to them each are greater than or equal to 8 μm, so that the pixel defining portions 350 have sufficiently large sizes to prevent color mixing or color spots.

Optionally, as described above, the display panel 10 further comprise light-emitting functional portions 510 and second electrodes 600, at least part of the light-emitting functional portions 510 are located in the isolation openings 460, and the second electrodes 600 are located on sides of the light-emitting functional portions 510 away from the base plate 100, the material of the isolation structure 400 comprises a conductive material, the second electrodes 600 are electrically connected with the isolation wall 420, so that a plurality of second electrodes 600 can be interconnected via the isolation wall 420 to form a surface electrode.

In some optional embodiments, the distance between two adjacent ones of the first electrodes 200 is greater than or equal to 5 μm.

In the display panel 10 provided in this embodiment, the distance between two adjacent ones of the first electrodes 200 is greater than or equal to 5 μm, which reduces the probability of adjacent first electrodes 200 being connected as a whole during the manufacturing process, thereby reducing the difficulty of manufacturing the first gap 210.

Please refer to FIGS. 1 to 16, embodiments of the first aspect of the present application further provides a display panel 10, comprising a base plate 100, first electrodes 200, insulating layers and an isolation structure 400. The first electrodes 200 are located on a side of the base plate 100; the insulating layers are located on sides of the first electrodes 200 away from the base plate 100 and enclose to form pixel openings 310, from which the first electrodes 200 are at least partially exposed; the isolation structure 400 is provided on sides of the insulating layers away from the base plate 100, wherein the isolation structure 400 comprises isolation walls 420 comprising first surfaces 422 away from the base plate 100 and second surfaces 423 facing the base plate 100, as well as first side surfaces 470 connecting the first surfaces 422 and the second surfaces 423. Surfaces of the insulating layers away from the base plate 100 comprise flat areas 302, orthographic projections of the first side surfaces 470 on the base plate 100 are located within the orthographic projections of the flat areas 302 on the base plate 100.

In the display panel 10 provided in the present application, the first electrodes 200 are at least partially exposed from the pixel opening 310, so that the first electrodes 200 can drive the plurality of light-emitting functional portions 510 of the display panel 10 to emit light for display. The isolation structure 400 is provided on the same side of the base plate 100 as the first electrodes 200 and is provided on the sides of the insulating layers away from the base plate 100. The flatness of the surfaces of the insulating layers will affect the form of the isolation structure 400. The surfaces of the insulating layers away from the base plate 100 comprise flat areas 302 with relatively flat surfaces. The orthographic projections of the first side surfaces 470 on the base plate 100 are located within the orthographic projections of the flat areas 302 on the base plate 100, so that the first side surfaces 470 are correspondingly located on the flat areas 302, which can improve the flatness of the first side surfaces 470, facilitate the overlapping of subsequent film layers, and improve the yield of the display panel 10.

Optionally, the flat areas 302 may be areas with smaller friction coefficient on the surfaces of the insulating layers away from the base plate 100, may be relatively flat areas on the surfaces of the insulating layers away from the base plate 100, or may be areas where the insulating layers do not overlap with the edges of the film layers located thereunder, so that the flat areas 302 will not be affected by the height difference of the edges of other film layers which form large height differences. Optionally, the distance difference between any two points in the flat areas 302 and the base plate 100 is less than or equal to a preset threshold value, which is, for example, 1 μm, 0.1 μm, 0.01 μm, etc., which can be determined by the user according to actual use requirements.

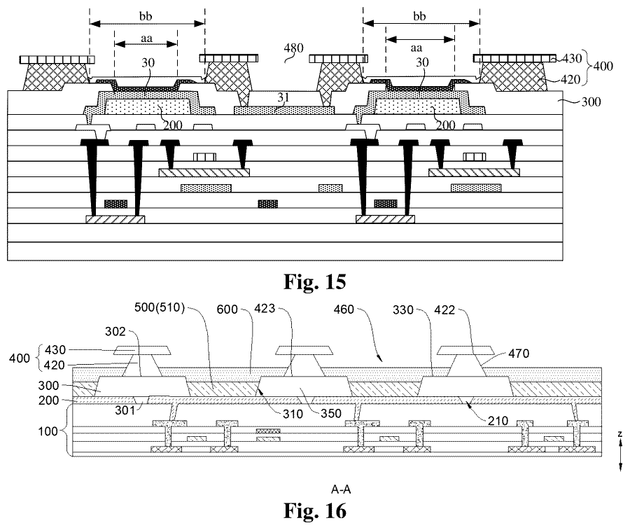

In some optional embodiments, as shown in FIG. 16, the insulating layers comprise second insulating layers 301 located in gaps between two first electrodes 200 adjacent to them and first insulating layers 300, the distances between the side surfaces of the second insulating layers 301 away from the base plate 100 and the base plate 100 in the thickness direction Z of the display panel 10 are equal to the distances between the side surfaces of the first electrodes 200 away from the base plate 100 and the base plate 100 in the thickness direction Z of the display panel 10. The first insulating layers 300 are located on the sides of the second insulating layers 301 away from the base plate 100 and cover the second insulating layers 301 and at least part of the first electrodes 200, and the side surfaces of the first insulating layers 300 away from the base plate 100 form flat areas 302.

In these optional embodiments, the second insulating layers 301 can be used to fill the first gaps 210 between adjacent ones of the first electrodes 200 to improve the height difference caused by providing the first electrodes 200. The first insulating layers 300 are covered on the second insulating layers 301 and the first electrodes 200, so that the first insulating layers 300 are provided on relatively flat surfaces, thereby improving the flatness of the surfaces of the first insulating layers 300 and the flatness of the isolation structure 400 provided on the first insulating layers 300.

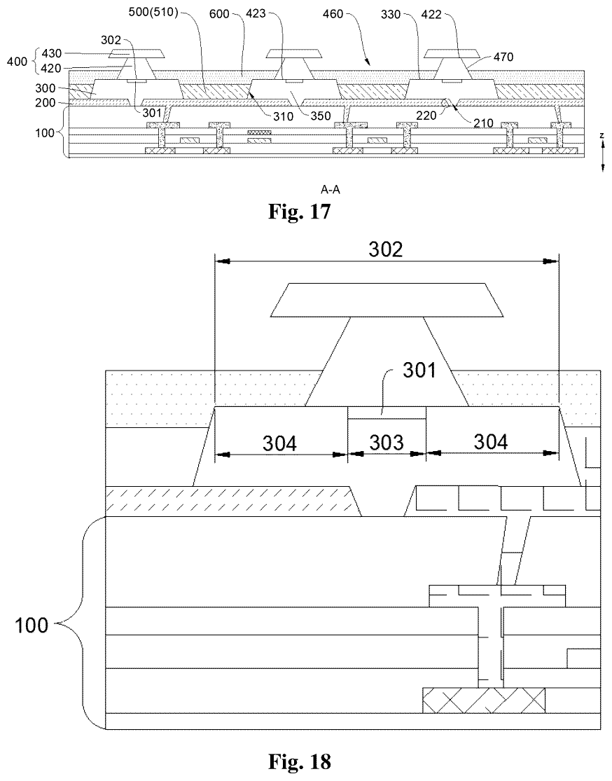

Alternatively, in some other embodiments, as shown in FIGS. 17 and 18, surfaces of the first insulating layers 300 away from the base plate 100 comprise first areas 303 and second areas 304. The first areas 303 form first recesses 320, orthographic projections of the first recesses 320 on the base plate 100 are staggered with the orthographic projections of the first electrodes 200 on the base plate 100, the second insulating layers 301 are located in the first recesses 320, the distances between the surfaces of the second insulating layers 301 away from the base plate 100 and the base plate 100 in the thickness direction Z of the display panel 10 are equal to the distances between the second areas 304 and the base plate 100 in the thickness direction Z of the display panel 10, and the second areas 304 and the surfaces of the second insulating layers 301 away from the base plate 100 form flat areas 302.

In these optional embodiments, due to the presence of the first electrodes 200, at least part of the first insulating layers 300 will fill the first gaps 210 between adjacent first electrodes 200, thereby forming first recesses 320 on the first insulating layers 300. By filling the second insulating layers 301 in the first recesses 320, the flatness of the surfaces of the insulating layers can be improved, thereby improving the flatness of the isolation structure 400 provided on the first insulating layers 300.

In some optional embodiments, the insulating layers comprise first insulating layers 300, sides of which away from the base plate 100 are provided with first recesses 320, orthographic projections of the first recesses 320 on the base plate 100 are staggered with the orthographic projections of the first electrodes 200 on the base plate 100. Due to the presence of the first electrodes 200, at least part of the first insulating layers 300 will fill the first gaps 210 between adjacent first electrodes 200, thereby forming the first recesses 320 on the first insulating layers 300, and making the first recesses 320 staggered with the first electrodes 200.

In some optional embodiments, as shown in FIG. 5, the orthographic projections of the flat areas 302 on the base plate 100 are staggered with the orthographic projections of the first recesses 320 on the base plate 100, or as shown in FIG. 3, the orthographic projections of the flat areas 302 on the base plate 100 are located within ranges of orthographic projections of bottoms of the first recesses 320 on the base plate 100. In other words, the flat areas 302 are outside the first recesses 320 and staggered with the first recess 320. The flat areas 302 are relatively flat, thus there will not be large height differences. Alternatively, the flat areas 302 are located in the first recesses 320 and will not pass through the height differences of the edges of the first recesses 320, so that the flatness of the flat area 302 can be improved, thereby ensuring the flatness of the first side surfaces of the isolation walls.

In some optional embodiments, the first electrodes 200 comprise first edge areas 220, orthographic projections of which on the base plate 100 are staggered with the flat areas 302. This can improve the effect of the height differences of the first edge areas 220 on the flatness of the flat areas 302, thereby reducing the effect on the flatness of the first side surfaces of the isolation walls, and reducing the defective rate of the subsequent film layers overlapping the first side surfaces of the isolation walls.

In some optional embodiments, the orthographic projections of at least part of the first edge areas 220 on the base plate 100 are staggered with the orthographic projections of the first side surfaces 470 on the base plate 100, thereby improving the effect of the height differences of the first edge areas 220 on the flatness of the first side surfaces 470.

In some optional embodiments, as shown in FIGS. 4 to 6, at least part of the orthographic projections of the first edge areas 220 on the base plate 100 are located within the orthographic projections of the first surfaces 422 or the second surfaces 423 with smaller orthographic projection areas on the base plate 100 on the base plate 100; or, as shown in FIG. 3, at least part of the orthographic projections of the first edge areas 220 on the base plate 100 are staggered with the orthographic projections of the isolation walls 420 on the base plate 100. That is, the first edge areas 220 may extend below the isolation walls 420 to stagger with the first side surfaces 470, or may extend outside the isolation walls 420 to stagger with the first side surfaces 470, as long as the first side surfaces 470 are provided in relatively flat areas.

As shown in FIG. 3 or 16, an embodiment of the first aspect of the present application further provides a display panel 10, comprising a base plate 100, first electrodes 200 and an isolation structure 400. The base plate 100 comprises pixel circuits 110 and first via holes 120; the first electrodes 200 are located on a side of the base plate 100 and on the sides of the first via holes 120 away from the pixel circuits 110, and the first electrodes 200 are connected with the pixel circuits 110 via the first via holes 120; the isolation structure 400 is provided on a side of the base plate 100 and is located on the same side of the base plate 100 as the first electrodes 200, the isolation structure 400 encloses a plurality of isolation openings 460, the isolation structure 400 is insulated from the first electrodes 200, and at least part of the first electrodes 200 are exposed from the isolation openings 460, the isolation structure 400 comprises isolation walls 420, orthographic projections of the first via holes 120 on the base plate 100 are staggered with orthographic projections of the isolation walls 420 on the base plate 100, thereby improving the effect of setting the first via holes 120 on the flatness of the isolation structure 400.

Embodiments of the second aspect of the present application further provides a display apparatus, comprising the display panel of any of the above embodiments. Since the display apparatus provided by the embodiments of the second aspect of the present application comprises the display panel of the above embodiments, the display apparatus provided by the embodiments of the second aspect of the present application has the beneficial effects of the display panel of any of the above embodiments, which will not be described in detail here.

The display apparatus in the embodiment of the present application comprises but is not limited to mobile phones, personal digital assistants (PDAs), tablet computers, e-books, televisions, access control systems, smart fixed phones, consoles, and other apparatuses with display functions. The display apparatus can be not only the mobile phone shown in FIG. 1, but also a tablet, mobile phone, watch, wearable device, and electronic devices such as vehicle-mounted display, camera display, television, and computer screen.

The above are only a specific implementations of the present application. Those skilled in the art can clearly understand that for the convenience and simplicity of description, the specific working processes of the systems, modules and units described above can refer to the corresponding processes in the aforementioned method embodiments, and will not be repeated here. It should be understood that the protection scope of the present application is not limited to this. Any skilled in the art familiar with the technical field can easily think of various equivalent modifications or replacements within the technical scope disclosed in this application, and these modifications or replacements should be comprised in the protection scope of this application.

What is claimed is:

1. A display panel, comprising:
a base plate;
a plurality of first electrodes distributed in an array on a side of the base plate and having first edge areas;
an isolation structure, provided on a side of the base plate, located on a same side of the base plate as the first electrodes, enclosing a plurality of isolation openings and insulated from the first electrodes, at least part of the first electrode exposed from the isolation openings, wherein the isolation structure comprises a plurality of isolation walls comprising first surfaces away from the base plate and second surfaces facing the base plate in a thickness direction of the display panel, first side surfaces connecting the first surfaces and the second side surfaces, and orthographic projections of at least part of the first edge areas on the base plate are staggered with orthographic projections of the first side surfaces on the base plate.

2. The display panel of claim 1, wherein areas of the orthographic projections of the first surfaces on the base plate each are different from areas of the orthographic projections of the second surfaces on the base plate, and at least part of the orthographic projections of the first edge areas on the base plate are located within the orthographic projections of the first surfaces or the second surfaces on the base plate with smaller orthographic projection areas on the base plate.

3. The display panel of claim 2, wherein the orthographic projections of the first surfaces on the base plate are located within the orthographic projections of the second surfaces on the base plate, and at least part of the orthographic projections of the first edge areas on the base plate are located within the orthographic projections of the first surfaces on the base plate.

4. The display panel of claim 3, wherein the first side surfaces are inclined toward a direction away from the isolation openings in a direction away from the base plate; or
the orthographic projections of the first edge areas on the base plate are located within the orthographic projections of the first surfaces on the base plate, or part of the orthographic projections of the first edge areas on the base plate are located within the orthographic projections of the first surfaces on the base plate, and the other part of the orthographic projections of the first edge areas on the base plate are staggered with the orthographic projections of the second surfaces on the base plate.

5. The display panel of claim 2, wherein the orthographic projection of the second surfaces on the base plate are located within the orthographic projections of the first surfaces on the base plate; at least part of the orthographic projections of the first edge areas on the base plate are located within the ranges of the orthographic projections of the second surfaces on the base plate;
the first side surfaces are inclined toward a direction close to the isolation openings in the direction away from the base plate.

6. The display panel of claim 2, further comprising a plurality of first insulating layers provided on sides of the first electrodes away from the base plate and filled gaps between adjacent first electrodes;
wherein the isolation structure is provided on sides of the first insulating layers away from the base plate, the sides of the first insulating layers away from the base plate are provided with first recesses, orthographic projections of which on the base plate are staggered with the orthographic projections of the first electrodes on the base plate.

7. The display panel of claim 6, wherein the orthographic projections of the first recesses on the base plate are within the ranges of the orthographic projections of the first surfaces or the second surfaces on the base plate with smaller orthographic projection areas on the base plate, and part of the isolation walls are located in the first recesses;
a plurality of third recesses are provided on sides of the isolation walls away from the base plate;
orthographic projections of the third recesses on the base plate at least partially overlap with the orthographic projections of the first recesses on the base plate;
or, the orthographic projections of the third recesses on the base plate are at least partially staggered with the orthographic projections of the first electrodes on the base plat.

8. The display panel of claim 7, wherein the isolation structure further comprises:
a plurality of barrier parts provided on sides of the isolation walls away from the base plate, orthographic projections of the isolation walls on the base plate being located within orthographic projections of the barrier parts on the base plate, at least part of the barrier parts being located in the third recesses; a plurality of second recesses are provided on sides of the isolation walls away from the isolation wall, orthographic projections of the second recesses on the base plate at least partially overlapping with the orthographic projections of the third recesses on the base plate.

9. The display panel of claim 1, wherein orthographic projections of the first edge areas on the base plate are staggered with orthographic projections of the isolation walls on the base plate.

10. The display panel of claim 9, further comprising first insulating layers provided on sides of the first electrodes away from the base plate, the isolation structure being provided on sides of the first insulating layers away from the base plate, a plurality of first recesses being provided on sides of the first insulating layers away from the base plate, orthographic projections of the first recesses on the base plate being staggered with the orthographic projections of the first electrodes on the base plate;
the orthographic projections of the isolation walls between sub-pixels adjacent to the isolation walls on the base plate are within the orthographic projections of the first recesses on the base plate.

11. The display panel of claim 9, wherein the base plate comprises a plurality of pixel circuits and a plurality of first via holes located between the pixel circuits and the first electrodes, the pixel circuits being electrically connected with the first electrodes via the first via holes, orthographic projections of the first via holes on a plane where the base plate is located being staggered with orthographic projections of the isolation walls on the plane where the base plate is located.

12. The display panel of claim 9, wherein, in the thickness direction of the base plate, the base plate comprises a plurality of pixel circuits and a plurality of first via holes located between the pixel circuits and the first electrodes, orthographic projections of the first via holes on a plane where the base plate is located being located within the ranges of orthographic projections of the isolation walls on the plane where the base plate is located, orthographic projections of the first via holes on the base plate being staggered with the orthographic projections of the first side surfaces on the base plate;
the display panel further comprises auxiliary electrodes electrically connected with the pixel circuits via the first via holes and electrically connected with the first electrodes, wherein the auxiliary electrodes are located on sides of the first electrodes away from the base plate;
or, the auxiliary electrodes are in contact with outer peripheral surfaces of the first electrodes.

13. The display panel of claim 12, wherein orthographic projections of the auxiliary electrodes on the base plate partially overlap with the orthographic projections of the isolation walls on the base plate and cover the first via holes;
or, in the thickness direction of the display panel, the thickness of the auxiliary electrodes each are smaller than the thickness of the first electrodes;
or, the auxiliary electrodes each have a thickness of 0.01 μm to 0.1 μm;
the isolation structure is provided with a plurality of light transmitting holes spaced apart from the isolation openings, and the display panel further comprises transparent conductive connecting portions provided in the same layer as the auxiliary electrodes and spaced apart from the auxiliary electrodes; wherein
the isolation structure surrounding the light transmitting holes is connected with the transparent conductive connecting portions, orthographic projections of the transparent conductive connecting portions on the base plate covering orthographic projections of the light transmitting holes on the base plate.

14. The display panel of claim 1, further comprising a plurality of first insulating layers provided on sides of the first electrodes away from the base plate, sides of the first insulating layers away from the base plate being provided with the isolation structure, the first insulating layers comprising a plurality of pixel defining portions enclosing pixel openings, orthographic projections of the pixel openings on the base plate at least partially overlap with orthographic projections of the first electrodes on the base plate;
the display panel further comprises light-emitting functional portions, at least part of the light-emitting functional portions are located in the isolation openings, the second electrodes being located on sides of the light-emitting functional portions away from the base plate; and
the isolation structure comprises conductive material, and the second electrodes and the isolation walls are electrically connected with each other.

15. A display panel, comprising:
a base plate;
first electrodes located on a side of the base plate,
insulating layers located on sides of the first electrodes away from the base plate and enclosing pixel openings, the first electrodes at least partially expose from the pixel openings;
an isolation structure provided on sides of the insulating layers away from the base plate;
wherein the isolation structure comprises isolation walls comprising first surfaces away from the base plate, second surfaces facing the base plate, and first side surfaces connecting the first surfaces and the second surfaces, surfaces of the insulating layers away from the base plate comprising flat areas, orthographic projections of the first side surfaces on the base plate being located within orthographic projections of the flat areas on the base plate.

16. The display panel of claim 15, wherein the insulating layers further comprise a plurality of first insulating layers and a plurality of second insulating layers,
the second insulating layers being located in gaps between two first electrodes adjacent to the second insulating layers, distances between surfaces of the second insulating layers away from the base plate and the base plate in a thickness direction of the display panel each being equal to distances between surfaces of the first electrodes away from the base plate and the base plate in the thickness direction of the display panel, the first insulating layers being located on the sides of the second insulating layers away from the base plate and covering the second insulating layers and at least part of the first electrodes, surface of the first insulating layers away from the base plate forming the flat areas,
or, surfaces of the first insulating layers away from the base plate comprises:
a plurality of first areas forming a plurality of first recesses, orthographic projections of the plurality of first recesses on the base plate are staggered with orthographic projections of the first electrodes on the base plate and the second insulating layers are located in the plurality of first recesses, and
second areas, distances between surfaces of the second insulating layers away from the base plate and the base plate in the thickness direction of the display panel being equal to distances between the second areas and the base plate in the thickness direction of the display panel, the second areas and the surfaces of the second insulating layers away from the base plate forming the flat areas.

17. The display panel of claim 15, wherein the insulating layers comprise a plurality of first insulating layers, sides of the plurality of first insulating layers away from the base plate are provided with first recesses, orthographic projections of the first recesses on the base plate are staggered with the orthographic projections of the first electrodes on the base plate.

18. The display panel of claim 17, wherein the orthographic projections of the flat areas on the base plate are staggered with the orthographic projections of the first recesses on the base plate, or the orthographic projections of the flat areas on the base plate are located within the ranges of an orthographic projections of bottoms of the first recesses on the base plate.

19. The display panel of claim 17, wherein the first electrodes comprise a plurality of first edge areas, orthographic projection of the plurality of first edge areas on the base plate are staggered with the flat areas;
orthographic projections of at least part of the first edge areas on the base plate are staggered with orthographic projections of the first side surfaces on the base plate;
at least part of the orthographic projections of the first edge areas on the base plate are located within the orthographic projections of the first surfaces or the second surfaces with smaller orthographic projection areas on the base plate;
or, at least part of the orthographic projections of the first edge areas on the base plate are staggered with the orthographic projections of the isolation walls on the base plate.

20. A display panel, comprising:
a base plate comprising a plurality of pixel circuits and a plurality of first via holes;
a plurality of first electrodes, located on a side of the base plate and sides of the first via holes away from the pixel circuits, and electrically connected with the pixel circuits via the first via holes;
an isolation structure, provided on a side of the base plate and located on the same side of the base plate as the first electrodes, enclosing a plurality of isolation openings, and insulated from the first electrodes, at least part of the first electrodes is exposed from the isolation openings, wherein
the isolation structure comprises a plurality of isolation walls, orthographic projection of which on the base plate are staggered with orthographic projections of the first via holes on the base plate.
